(19) United States
(12) Patent Application Publication
(10) Pub. No.: US 2018/0238963 A1
(43) Pub. Date: Aug. 23, 2018

(54) OVERRIDING A SIGNAL IN A SEMICONDUCTOR CHIP

(71) Applicant: Infineon Technologies AG, Neubiberg (DE)

(72) Inventors: Pankaj Moharikar, Bangalore (IN); Jayakrishna Guddeti, Bangalore (IN)

(21) Appl. No.: 15/438,240

(22) Filed: Feb. 21, 2017

(51) Int. Cl. G01R 31/317; G01R 31/3177

(52) U.S. Cl. CPC G01R 31/31704; G01R 31/3177; G01R 31/31723; G01R 31/31712

(57) ABSTRACT

A semiconductor chip, including an Intellectual Property (IP) core; and a signal forcing circuit located within the IP core, or located at a boundary of the IP core coupling the IP core with another IP core, the signal forcing circuit configured to: transmit an input signal received by the IP core as an output signal; and in response to a trigger condition, forcing an override signal as the output signal.

### BACKGROUND

The present disclosure relates to post-silicon validation of a microcontroller with one or more Central Processing Units (CPUs), and on-chip bus connectivity between different Intellectual Property (IP) cores.

Post-silicon validation is a critical step in order to deliver high quality microcontrollers. However, this validation is becoming more costly and time consuming due to an increased number of IP cores on a semiconductor chip. Some IP cores are developed in-house, whereas others are purchased. These diverse IP cores are then combined to create a microcontroller on a semiconductor chip. Due to limited control of IP core interconnects, more complex test cases and costlier setups are needed in order to create various error and functional scenarios to validate chip functionality. It is becoming more complex to create corner case scenarios, error conditions, and events for microcontroller silicon validation. Further, automotive microcontrollers and software need to undergo additional safety testing, which requires the creation of error scenarios and complex events in silicon. Without intrusive changes in the IP cores, currently this is not feasible.

Prior solutions rely on internal design mechanisms to create directed error scenarios. There is limited coverage as this is an intrusive and time consuming process to implement in Register-Transistor Logic (RTL). Also, this may not always be feasible, especially when IP cores are reused from different sources.

### BRIEF DESCRIPTION OF THE DRAWINGS

FIG. 1 illustrates a schematic diagram of signal forcing circuits in a semiconductor chip in accordance with an aspect of the disclosure.

FIG. 2 illustrates a schematic diagram of a signal forcing circuit in accordance with an aspect of the disclosure.

FIG. 3 illustrates a schematic diagram of Single-Bit Override (SBO) circuit in accordance with an aspect of the disclosure.

FIG. 4 illustrates a schematic diagram of Multi-Bit Override (MBO) circuit in accordance with an aspect of the disclosure.

FIG. 5 illustrates a schematic diagram of trigger subcircuit in accordance with an aspect of the disclosure.

FIG. 6 illustrates a flowchart of a method of testing a semiconductor chip in accordance with an aspect of the disclosure.

### DETAILED DESCRIPTION

The present disclosure is directed to a modular, customizable signal forcing circuit, which is either integrated into a semiconductor chip after a design is complete, known as late binding, or alternatively, integrated into an IP core of the semiconductor chip during the design stage. The signal forcing circuit enables selective forcing of override signals in silicon based on complex trigger conditions, continuous monitoring of different signals, and determining when to force an override signal with a particular value. The signal forcing circuit also supports forcing of multi-bit on-chip buses.

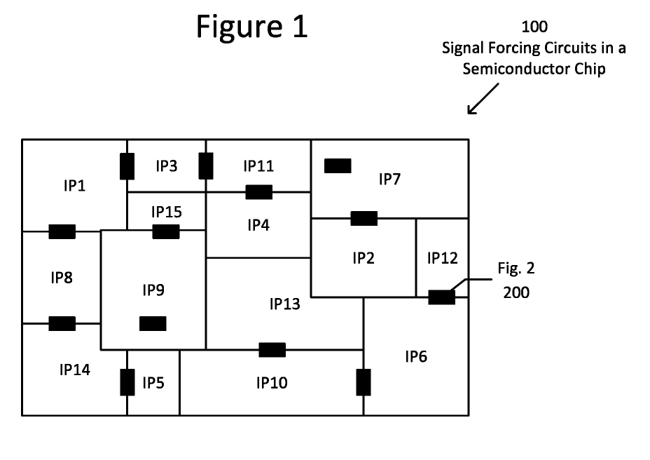

FIG. 1 illustrates a schematic diagram of signal forcing circuits in a semiconductor chip (or microcontroller silicon) 100 in accordance with an aspect of the disclosure.

The signal forcing circuits, which are shown in the figure as black rectangles, can be integrated with existing IP cores (IP1-IP15 in the figure) by placing the circuits to transfer an interface signal between IP cores. A signal forcing circuit can be integrated into the silicon after synthesis of Register-Transistor Logic (RTL) by placing the circuit at a boundary of an IP core and routing its interface signals to the signal forcing circuit. The signal forcing circuits can therefore be bound late in the development of the semiconductor chip 100, providing flexibility in terms of selecting signals to be forced and placement of signal forcing circuits. Configuration registers of the signal forcing circuits can be routed on a separate register configuration bus, which can be either dedicated for signal forcing circuits across the semiconductor chip 100 or shared with other configuration buses.

Examples of IP cores (IP1-IP15) include, but are not limited to, Direct Memory Access (DMA), Radar Interface (RIF), Signal Processing Unit (SPU), Generic Timer Module (GTM), Controller Area Network (CAN), Inter-Integrated Circuit (I²C), Analog-to-Digital Converter (ADC), and Hardware Security Module (HSM).

Alternatively or in addition to late binding at the boundary of the IP core, the signal forcing circuits may be located within any of the IP cores, such as shown In FIG. 1 in IP7 and IP9. Thus not only an external signal, but also a signal internal to the IP core may be forced with an override signal.

By default, the signal forcing circuit is bypassed and an input signal of the signal forcing circuits is driven to the output. When the particular override signal of the signal forcing circuit is enabled and triggered, then an override signal is forced as the output signal for a duration as discussed in detail below.

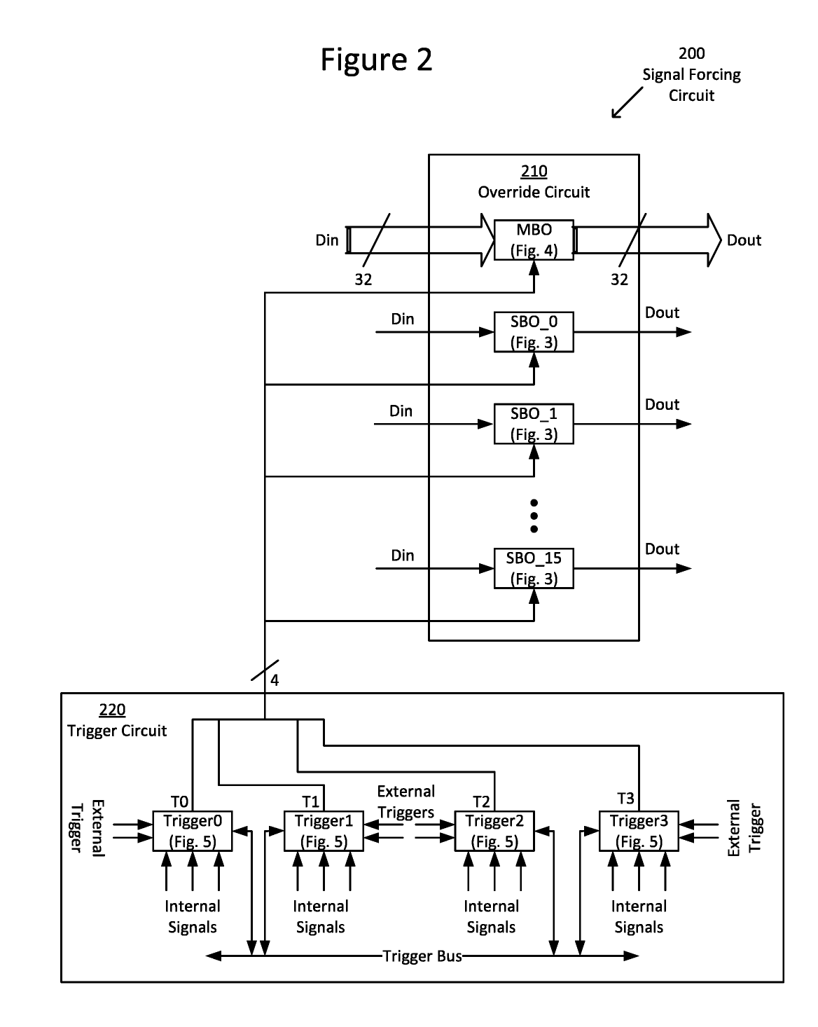

FIG. 2 illustrates a schematic diagram of a signal forcing circuit 200 in accordance with an aspect of the disclosure.

The signal forcing circuit 200 comprises an override circuit 210 and a trigger circuit 220.

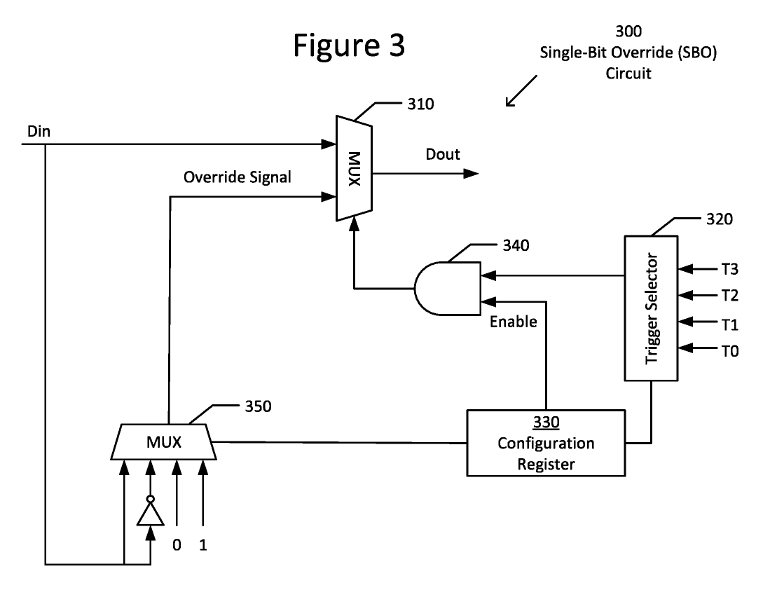

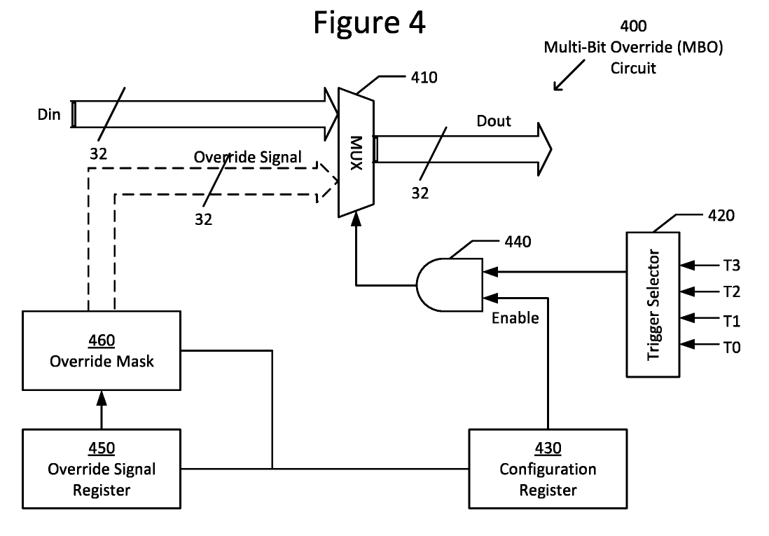

The override circuit 210 comprises a Multi-Bit Override (MBO) circuit and a plurality of Single-Bit Override (SBO) circuits, though the disclosure is not limited in this respect. There may be any number of MBO and SBO circuits as suitable for the intended purpose. The SBO and MBO circuits will be described in more detail below with respect to FIGS. 3 and 4, respectively.

The override circuit 210 is configured to either be bypassed by transmitting an input signal Din of the signal forcing circuit 200 as an output signal Dout, or in response to a trigger condition, or force an override signal as the output signal Dout. Hardware registers (not shown) within the override circuit 210 to enable/disable signal forcing, and select one or more triggers from a plurality of triggers.

The override circuit 210 may be optimized based on signal width, SBO and MBO, or a override bus implementation. A MBO implementation, to be discussed below with respect to FIG. 4, may be more useful for bus interfaces where multiple bits are to be forced simultaneously.

The trigger circuit 220 comprises trigger subcircuits (Trigger0 . . . Trigger3). In this example, there are four trigger subcircuits, but of course the disclosure is not limited in this respect. The trigger circuit 200 may have any number of trigger subcircuits as suitable for a particular design. The example shown in the figure may have single-bit override signals forced independently, and with an option to select a trigger signal T0 . . . T3 from the four available trigger subcircuits (Trigger0 . . . Trigger3). Having a plurality of trigger subcircuits enables greater flexibility in forcing each signal based on a different condition. The plurality of trigger subcircuits may also be cascaded to create more complex triggers.

Each of the plurality of trigger subcircuits (Trigger0 . . . Trigger3) may be coupled to a trigger bus, along with configuration registers, though the disclosure is not limited in this respect. Also, the trigger subcircuits (Trigger0 . . . Trigger3) may receive signals that are internal to the IP core, and/or external to the IP core via the trigger bus. The trigger subcircuits (Trigger0 . . . Trigger3) are configured to output a trigger signal (T0 . . . T3, respectively) to be output to the override circuit 210 when a respective trigger condition, defined by the respective trigger subcircuit (Trigger0 . . . Trigger3), is met.

FIG. 3 illustrates a schematic diagram of Single-Bit Override (SBO) circuit 300 in accordance with an aspect of the disclosure. The SBO circuit 300 is located within the override circuit 200 of FIG. 2.

The SBO circuit 300 comprises a first multiplexer 310, a trigger selector 320, a configuration register 330, an AND gate 340, and a second multiplexer 350.

The first multiplexer 310 is configured to select, based on a select signal received from AND gate 340, whether to pass the input signal Din as the output signal Dout, or force an override signal as the output signal Dout. The input signal Din, the output signal Dout, and the override signal of the SBO circuit 300 are each a signal of a single bit.

The second multiplexer 350 is configured to select, based on a select signal received from the configuration register 330, the override signal. The override signal may be, for example, a logic 0, a logic 1, an inverted version of the input signal Din, or the input signal Din. Of course the disclosure is not limited to these particular override signal values, but may be any value as suitable.

The configuration register 330 has outputs coupled to the AND gate 340, the trigger selector 320, and the second multiplexer 350. the configuration register 330 is configured by a user to store in registers values indicating when to enable the override signal via the AND gate 340, which trigger signal (T0-T3) to select via the trigger selector 320, and the override signal value to be output by the second multiplexer 350.

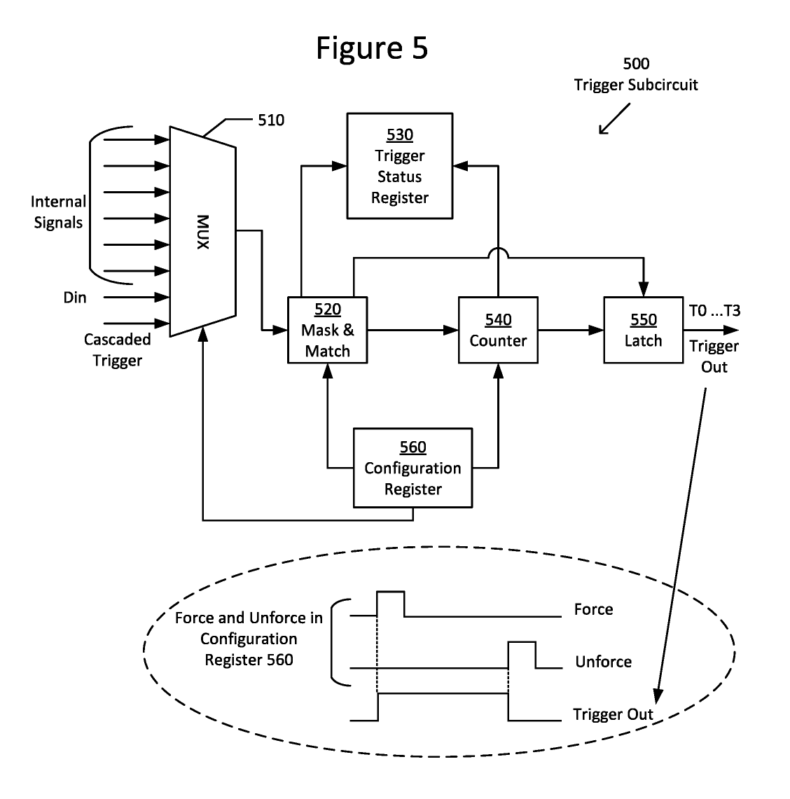

The trigger selector 320 is configured to select one or more trigger signals T0 . . . T3 from a plurality of trigger signals based on a select signal received from the configuration register 330. These trigger signals T0 . . . T3 are received from a trigger subcircuit 500, to be described below with respect to FIG. 5.

The AND gate 340 is configured to transmit the select signal to the first multiplexer 310 when it receives both the enable signal from the configuration register 330 and a trigger signal T0 . . . T3 from the trigger selector 320. The trigger selector 320 is configured to regularly output to the AND gate 340 its trigger signals T0 . . . T3. The enable signal is output by the configuration register 330 based on when the user decides to force the override signal as the output signal Dout, during one or more selected trigger conditions, as opposed to the input signal Din being the output signal Dout.

FIG. 4 illustrates a schematic diagram of Multi-Bit Override (MBO) circuit 400 in accordance with an aspect of the disclosure. The MBO circuit 400 is located within the override circuit 200 of FIG. 2.

The MBO circuit 400 comprises a multiplexer 410, a trigger selector 420, a configuration register 430, an AND gate 440, an override signal register 450, and an override mask 460.

The multiplexer 410, the trigger selector 420, the configuration register 430, and the AND gate 440 function similarly to the first multiplexer 310, the trigger selector 320, the configuration register 330, and the AND gate 340, respectively, of FIG. 3 described above. For the sake of brevity, their descriptions will not be repeated here. A main difference between the SBO 300 of FIG. 3 and the MBO 400 of FIG. 4, is the override signal, which is a multi-bit signal rather than a single-bit signal.

The override signal register 450 is configured to store override signals a user wants to be forced during particular trigger conditions. These stored override signals are user defined.

The override mask 460 is configured to mask out particular portions of an override signal that a user may not want to force a change in the input signal Din during an override. These portions of the input signal Din may represent, for example, a transaction identification, a source identification, a destination identification, etc. In such a case the user may cause only the data portion of the input signal Din to be forced to be overridden by the override signal. The override mask 460 is thus configured to output an override signal as a multi-bit override signal based on an override signal received from the override signal register 450. The input signal Din is shown in this example as being 32 bits, but of course this is merely exemplary.

FIG. 5 illustrates a schematic diagram of trigger subcircuit 500 in accordance with an aspect of the disclosure. The trigger subcircuit 500 is shown in FIG. 2 as Trigger0 . . . Trigger3. The trigger subcircuit 500 provides various configurability options to define trigger conditions for a signal override.

The trigger subcircuit 500 comprises a multiplexer 510, a mask & match circuit 520, a trigger status register 530, a counter 540, a latch 550, and a configuration register 560.

The trigger subcircuit 500 is configured to monitor one or more internal signals to detect a trigger condition. When a trigger condition is detected, the trigger subcircuit 500 outputs a trigger signal T0 . . . T3 to cause the override circuit 210 to force the output signal Dout of the signal forcing circuit 200 to be a user-defined override signal. Again, the default situation, that is, when there is no trigger condition, is for the override circuit 210 to pass the input signal Din through as the output signal Dout.

The multiplexer 510 is configured to select, based on a select signal received from the configuration register 560 which stores trigger conditions, between a plurality of internal signals, the input signal Din, and a cascaded trigger signal. The cascaded trigger signal is received from another trigger subcircuit 500, and is used to cascade a plurality of trigger subcircuits 500 to create complex trigger scenarios.

The mask & match circuit 520, which receives the output of the multiplexer 510, is configured to mask the input signal Din and determine when there is a match between the masked input signal and a reference signal as a trigger condition to start forcing the override signal.

The counter 540 is configured to create timer based triggers. For single cycle forcing, the counter 540 can be set with a value of 1. The counter 540 should be configured with a maximum value on which it will be triggered. Also, the counter 540 may be configured to start counting on a particular input signal transition. Alternatively, the counter 540 can be started by application software transmitting to the counter 540 a start bit. It is noted that the mask & match counter 520 and the counter may be used independently or together based on user requirement.

The trigger status register 530 is configured to store a value indicating the status of a trigger. The status may be whether a trigger occurred, whether the trigger is idle, the trigger is active, etc.

The configuration register 560 is configured to store user-defined start and stop trigger conditions for forcing and unforcing the override signal. When a trigger signal output is 1, the output signal Dout is the override signal, otherwise the output signal Dout is the input signal Din. Of course this is assuming that the override circuit is enabled, as discussed above with respect to FIG. 3.

The latch 550 is configured to latch a trigger signal T0 . . . T3 until a stop event occurs. This allows the trigger subcircuit 500 to reuse the mask & match circuit 520 and the counter 540 after the trigger signal starts to detect a stop point of the trigger signal T0 . . . T3, that is, the override signal. There may be independent configuration registers 560 to define the start and stop trigger conditions.

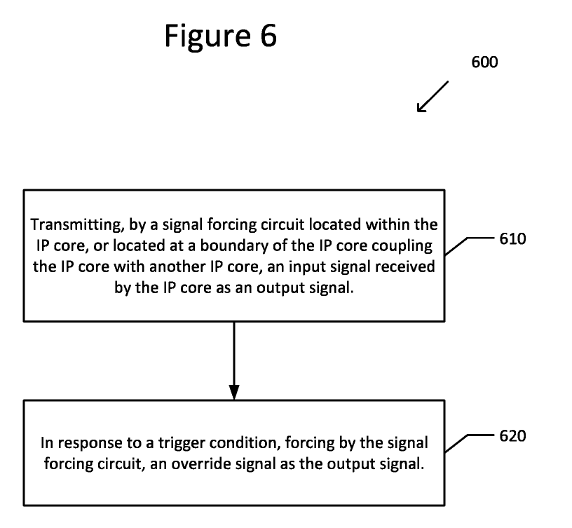

FIG. 6 illustrates a flowchart 600 of a method of testing a semiconductor chip 100 in accordance with an aspect of the disclosure.

In Step 610, a signal forcing circuit 200 located within an IP core (IP1 . . . IP15), or located at a boundary of the IP core (IP1 . . . IP15) coupling the IP core (IP1 . . . IP15) with another IP core (IP1 . . . IP15), transmits an input signal received by the IP core (IP1 . . . IP15) as an output signal Dout.

Then, in Step 620, in response to a trigger condition, the signal forcing circuit 200 forces, an override signal as the output signal Dout.

The output signal Dout may be forced with an override signal under any number of trigger conditions. The override signal forcing may be based on a predefined event, for example, after a reset of an IP core or any other signal transition as desired, based on expiration of counter value to achieve a fixed delay, or a combination of these conditions. Further, the override signal forcing may be based on cascaded trigger conditions or after a plurality of trigger conditions are met. Even further, the override signal forcing may be immediate based on software control.

The duration of the override signal forcing may be fixed based on a counter value, based on an event or signal transition, or a combination of these conditions. Alternatively, the duration may be permanent, last a single cycle, or any number of clock cycles as desired.

A signal forcing circuit may have any number of override signals forced. Also, the number of trigger subcircuits is not limited, and may be any number as suitable for a given design. The signal forcing circuit RTL is flexible to configure for any number of instances and generate a corresponding netlist. The signal forcing circuits thus may be easily customized for each IP core/interface and save die area.

The signal forcing circuit described herein is advantageous over prior circuits in many respects. This circuit is an easy way to create complex error scenarios by actively forcing error signals, or forcing signals in silicon to create error scenarios. The circuit also reduces test content complexity by providing silicon support to create complex micro-architectural scenarios. It is an easier way to debug and design workarounds. There is reduced complexity of setups to create error scenarios. The signal forcing circuit also facilitates easier testing of safety standards and compliance by injecting errors in silicon. There is testing of application software by creating a corner case scenario. The circuit provides a less expensive way to implement a workaround by using either continuous signal forcing (to alter a signal state) or by actively forcing signals based on trigger conditions. There is also a faster time to market by reducing the number of silicon stepping as bug workarounds can be implemented without design change.

For the purposes of this discussion, the term “circuit” shall be understood to be circuit(s), processor(s), logic, or a combination thereof. For example, a circuit can include an analog circuit, a digital circuit, state machine logic, other structural electronic hardware, or a combination thereof.

While the foregoing has been described in conjunction with exemplary aspects, it is understood that the term “aspect” is merely meant as an example, rather than the best or optimal. Accordingly, the disclosure is intended to cover alternatives, modifications and equivalents, which may be included within the scope of the disclosure.

Although specific embodiments have been illustrated and described herein, it will be appreciated by those of ordinary skill in the art that a variety of alternate and/or equivalent implementations may be substituted for the specific embodiments shown and described without departing from the scope of the present disclosure. This disclosure is intended to cover any adaptations or variations of the specific embodiments discussed herein.

What is claimed is:

1. A semiconductor chip, comprising:
an Intellectual Property (IP) core; and
a signal forcing circuit located within the IP core, or located at a boundary of the IP core coupling the IP core with another IP core, the signal forcing circuit configured to:
transmit an input signal received by the IP core as an output signal; and
in response to a trigger condition, forcing an override signal as the output signal.

2. The semiconductor chip of claim 1, wherein the signal forcing circuit comprises:
a trigger circuit configured to, in response to the trigger condition, output a trigger signal; and
an override circuit coupled to the trigger circuit, and configured to, in response to receiving the trigger signal, forcing the override signal as the output signal.

3. The semiconductor chip of claim 2, wherein the trigger condition is a predetermined event.

4. The semiconductor chip of claim 3, wherein the predetermined event is a reset of the IP core or the other IP core.

5. The semiconductor chip of claim 2, wherein the trigger circuit comprises a counter, and the trigger condition is expiration of the counter.

6. The semiconductor chip of claim 2, wherein:
the trigger circuit comprises a plurality of trigger subcircuits configured to generate a plurality of respective trigger signals based on a plurality of respective trigger conditions, and
the override circuit is configured to, in response to receiving any of the plurality of trigger signals, forcing the override signal as the output signal.

7. The semiconductor chip of claim 6, wherein the plurality of trigger subcircuits is a plurality of cascaded trigger subcircuits, and the override circuit is configured to, in response to receiving the plurality of trigger signals, force the override signal as the output signal.

8. The semiconductor chip of claim 2, wherein the trigger condition is software-controlled.

9. The semiconductor chip of claim 8, wherein the software-controlled trigger condition is based on content of a configuration register located within the semiconductor chip.

10. The semiconductor chip of claim 8, wherein the software controlled trigger condition is based on a signal received from external the IP core.

11. The semiconductor chip of claim 2, wherein the trigger circuit comprises a counter, and the trigger circuit is configured to output the trigger signal upon expiration of the counter.

12. The semiconductor chip of claim 2, wherein the trigger circuit comprises a latch configured to latch the trigger signal until a stop event occurs.

13. The semiconductor chip of claim 2, wherein the override signal is forced for a single clock cycle.

14. The semiconductor chip of claim 2, wherein the trigger circuit comprises a mask and match circuit configured to mask a portion of the input signal and is configured to determine if there is a match between the masked input signal and a reference signal as the trigger condition.

15. The semiconductor chip of claim 3, wherein the override circuit comprises a Single-Bit Override (SBO) circuit comprising:
a multiplexer configured to select the override signal.

16. The semiconductor chip of claim 15, wherein the override signal is selected from a group of signals consisting of: a logic 0, a logic 1, an inverted version of the input signal, and the input signal.

17. The semiconductor chip of claim 3, wherein the override circuit comprises a Multi-Bit Override (MBO) circuit, comprising:
an override mask configured to mask out a selected portion of the override signal so that a corresponding portion of the input signal is not forced to be overridden by the override signal.

18. The semiconductor chip of claim 1, wherein the semiconductor chip is a microcontroller.

19. A method of testing a semiconductor chip having an Intellectual Property (IP) core, the method comprising:
transmitting, by a signal forcing circuit located within the IP core, or located at a boundary of the IP core coupling the IP core with another IP core, an input signal received by the IP core as an output signal; and
in response to a trigger condition, forcing by the signal forcing circuit, an override signal as the output signal.

20. The method of claim 19, further comprising:
integrating the signal forcing circuit in the semiconductor chip subsequent to design of the semiconductor chip.
